(19) United States
(12) Patent Application Publication
(10) Pub. No.: US 2026/0150199 A1
(43) Pub. Date: May 28, 2026

(54) ELECTRONIC PACKAGE AND METHOD FOR FORMING THE SAME

(71) Applicant: JCET STATS ChipPAC Korea Limited, Incheon (KR)

(72) Inventors: WonSang RHEE, Incheon (KR); HunTeak LEE, Gyeonggi-do (KR); KyoungHee PARK, Seoul (KR)

(21) Appl. No.: 19/399,666

(22) Filed: Nov. 25, 2025

(30) Foreign Application Priority Data
Nov. 26, 2024 (CN) 202411700666.8

(51) Int. Cl. H05K 3/346; H05K 1/181; H05K 3/341; H05K 3/3485

(52) U.S. Cl. CPC H05K 3/346; H05K 1/181; H05K 3/3442; H05K 3/3485; H05K 2201/10992; H05K 2203/047

(57) ABSTRACT

Provided is a method for forming an electronic package, comprising: providing a substrate including a first conductive pad where a terminal of a first component is to be mounted and a second conductive pad where a terminal of a second component is to be mounted, the first conductive pad is adjacent to the second; forming a first solder paste on the first conductive pad; reflowing to form a first solder layer; forming a second solder paste on the first solder layer and the second conductive pad; placing the first and second components on the substrate with terminal of the first component contacting the second solder paste on the first solder layer and terminal of the second component contacting the second solder paste on the second conductive pad; reflowing the second solder paste to mount the first and second components.

### TECHNICAL FIELD

The present application generally relates to semiconductor technologies, and more particularly, to an electronic package and a method for forming an electronic package.

### BACKGROUND OF THE INVENTION

The semiconductor industry is constantly faced with complex integration challenges as consumers want their electronic products to be lighter, smaller and have higher performance with more and more functionalities. Conventionally, in an electronic package, various electronic components need to be attached onto a substrate to achieve desired electrical interconnection. In order to accommodate the various electronic components in a limited space on the substrate, a tight layout may be implemented where electronic components are very close to each other. However, as illustrated below, in such tight layout, an undesired solder bridge between adjacent electronic components may be formed during a soldering process for attaching electronic components on the substrate, especially between adjacent terminals of two electronic components.

Referring to FIG. 1A and FIG. 1B, sectional views of a portion of a substrate 100 before and after a soldering or reflow process are shown. The substrate 100 includes two conductive pads 110 and 120 formed thereon, each of which is used for mounting a terminal of one of two adjacent electronic components 150 and 160 using surface-mount technology (SMT), for example. As shown in FIG. 1A, the first conductive pad 110 and the second conductive pad 120 are each applied with solder paste 130, 140. The terminal 151 of the first electronic component 150 is placed on the first conductive pad 110 via the solder paste 130, while the terminal 161 of the second electronic component 160 is placed on the second conductive pad 120 via the solder paste 140. Referring to FIG. 1B, after the reflow process, the terminals 151 and 161 are metallurgically bonded to the reflowed solder paste, thereby forming electrical connections to the conductive pads 110 and 120, respectively.

However, there is a risk of forming a solder bridge between the two conductive pads 110 and 120 before and after the reflow step. Firstly, when the electronic components 150 and 160 are placed onto the substrate 100, the solder paste underneath may be squeezed out of the corresponding conductive pads. Secondly, during the reflow process, the solder paste may be melted and then flow to cover an expanded area on the substrate 100, which may be out of the conductive pads. As a result, a distance D1 between the reflowed solder paste on the two adjacent conductive pads 110 and 120 may be too small, or even reach zero, increasing the risk of an undesired solder bridge or short circuit between the two electronic component 150 and 160. In other words, adjacent solder paste may come into contact with each other after reflowing or at a later stage. This may result in malfunction of the electronic package and reduce the overall yield of the electronic package.

### Therefore, a need exists for an improved method for forming an electronic package

### SUMMARY OF THE INVENTION

An objective of the present application is to provide a method for forming an electronic package, with an improved effect in avoiding solder bridges or short defects in an electronic package.

According to an aspect of the present application, a method for forming an electronic package is provided, comprising: providing a substrate, wherein the substrate comprises a first conductive pad where a terminal of a first electronic component is to be mounted and a second conductive pad where a terminal of a second electronic component is to be mounted, wherein the first conductive pad is adjacent to the second conductive pad; forming a first solder paste on the first conductive pad; reflowing the first solder paste on the first conductive pad to form a first solder layer; forming a second solder paste on the first solder layer and on the second conductive pad, respectively; placing the first electronic component and the second electronic component on the substrate such that the terminal of the first electronic component is in contact with the second solder paste on the first solder layer, and the terminal of the second electronic component is in contact with the second solder paste on the second conductive pad; and reflowing the second solder paste to mount the first electronic component and the second electronic component onto the substrate. The reflowing processes described herein refer to any method suitable for melting and solidifying solder paste to connect electronic components to a printed circuit board, such as convection reflow, infrared reflow, vapor phase reflow, or hybrid reflow.

According to another aspect of the present application, an electronic package formed with the above method is provided.

According to a further aspect of the present application, an electronic device is provided, comprising: a substrate; a first conductive pad and a second conductive pad on the substrate, wherein the first conductive pad is adjacent to the second conductive pad; a first solder layer formed on the first conductive pad; a second solder layer formed on the first solder layer and on the second conductive pad, respectively; a first electronic component with a terminal mounted on the first conductive pad via the first solder layer and the second solder layer; a second electronic component with a terminal mounted on the second conductive pad via the second solder layer.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1A illustrates a sectional view of a portion of a conventional substrate before soldering.

FIG. 1B illustrates a sectional view of a portion of a conventional substrate after soldering.

FIG. 2 illustrates a flowchart of a method for forming an electronic package according to an embodiment of the present application.

FIGS. 3A to 3F illustrate sectional views of steps of the method shown in FIG. 2 according to an embodiment of the present application.

FIGS. 4A and 4B illustrate sectional views of two steps of the method shown in FIG. 2 according to another embodiment of the present application.

FIG. 5 illustrates a partial sectional view of the electronic package formed using the method shown in FIG. 2 according to an embodiment of the present application.

FIG. 6 illustrates a partial top view of an electronic device according to an embodiment of the present application.

The same or similar reference numbers will be used throughout the drawings to refer to the same or corresponding parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature’s relationship to another element(s) or feature(s) as illustrated in the Figures. The spatially relative terms are intended to encompass different orientations of the device in use or operation in addition to the orientation depicted in the Figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

In an electronic device such as an electronic package, various components can be integrated onto a same substrate. Traditionally, these components are attached to the substrate using a soldering process. To accommodate the components within a limited space of the substrate, a layout of the components on the substrate needs to be carefully designed. For example, electrical isolation should be ensured for components which are adjacent to each other, if no signals or voltages need to be transmitted between them. However, as illustrated above, solder paste on adjacent conductive pads may form solder bridges after a reflow process, if a distance between the adjacent conductive pads is too small, leading to undesired electrical connections such as short circuits. In order to address the above issue, a method for forming an electronic package that improves separation and isolation between adjacent electronic components is proposed in the present application. The method can prevent significant reshaping of solder paste during the reflow process, and thus avoid undesired solder bridges or short circuits.

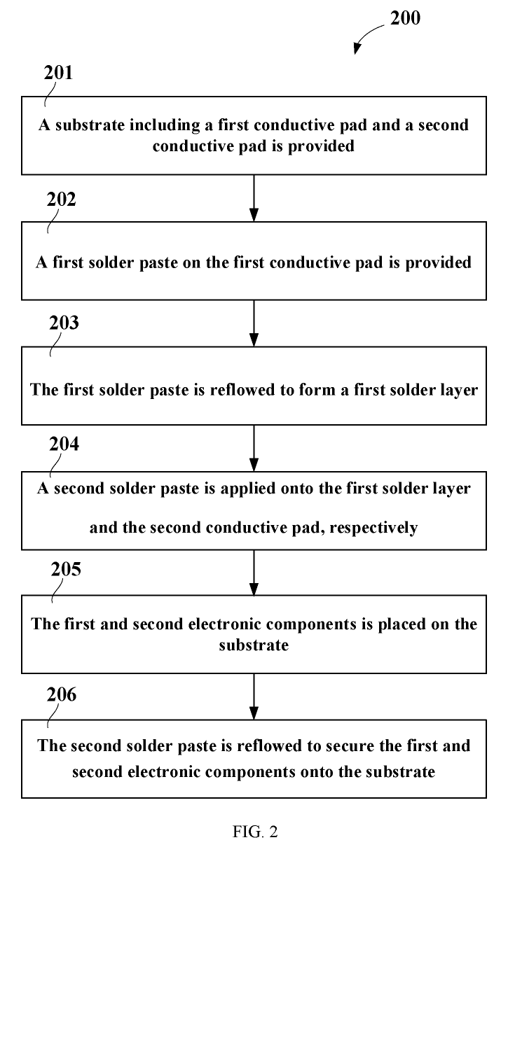

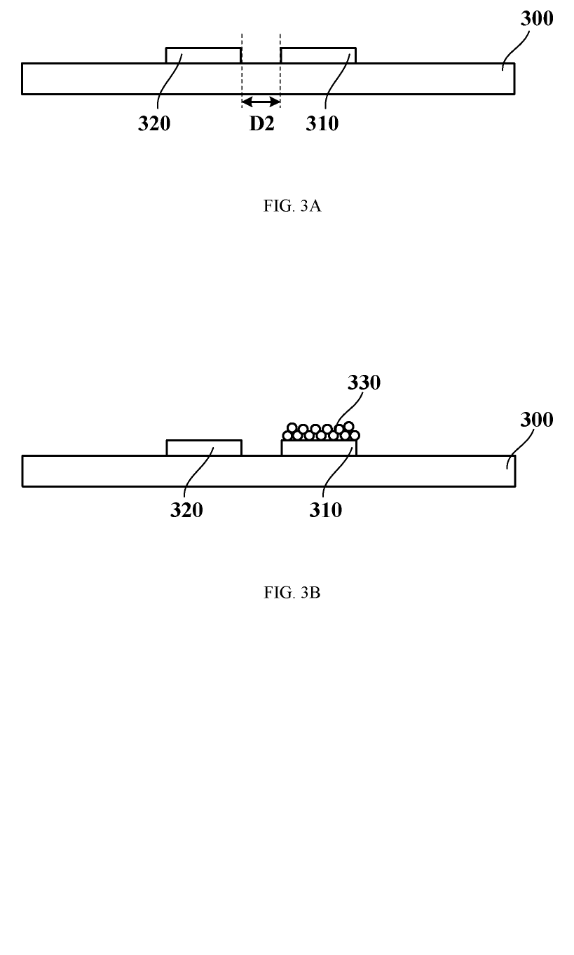

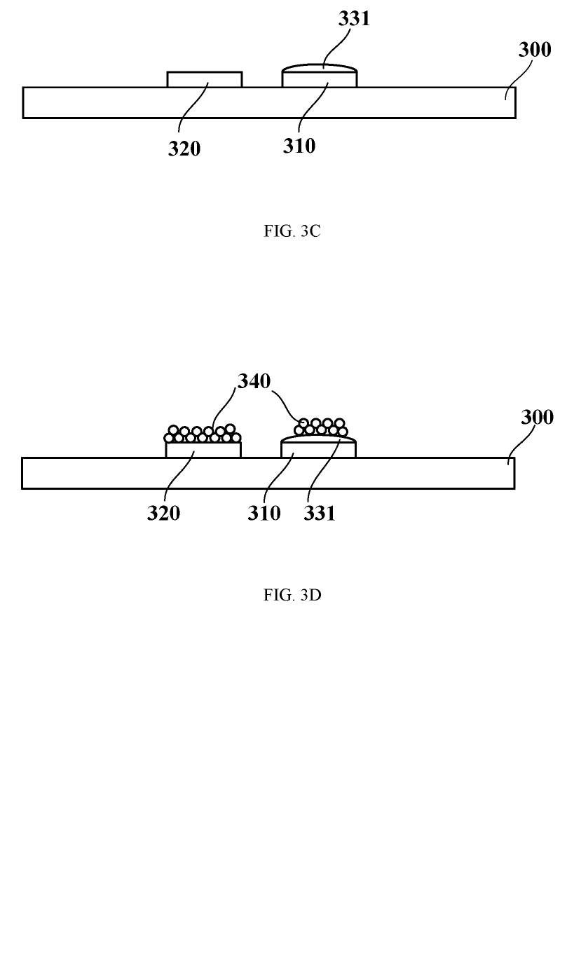

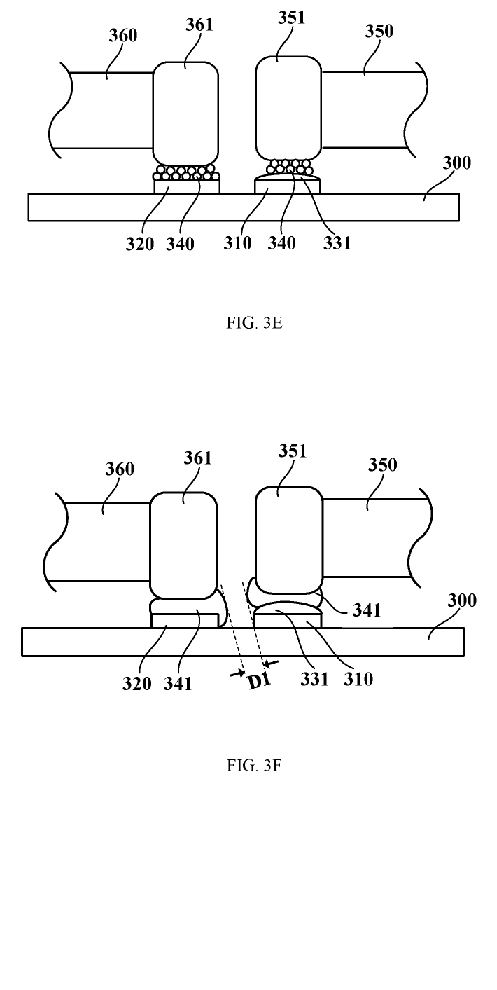

FIG. 2 illustrates a flowchart of a method 200 for forming an electronic package according to an embodiment of the present application. FIGS. 3A to 3F illustrate sectional views of steps of the method 200 according to an embodiment of the present application.

As shown in FIG. 2, the method 200 begins with step 201, where a substrate is provided. The substrate includes a first conductive pad where a terminal of a first electronic component is to be mounted, and a second conductive pad where a terminal of a second electronic component is to be mounted. The first conductive pad is positioned adjacent to the second conductive pad. In step 202, a first solder paste is applied onto the first conductive pad. In step 203, the first solder paste on the first conductive pad is reflowed to form a first solder layer. In step 204, a second solder paste is applied onto the first solder layer and to the second conductive pad. The second solder paste may have a melting characteristic different from that of the first solder paste. For example, the second solder paste may have a melting temperature lower than that of the first solder paste. It can be appreciated that the first and second solder pastes can be applied using any suitable methods, such as stencil printing, screen printing, pin transfer, or jet printing.

Next, in step 205, the first and second electronic components are placed onto the substrate such that the terminal of the first electronic component is in contact with the second solder paste on the first solder layer, and the terminal of the second electronic component is in contact with the second solder paste on the second conductive pad. In some preferred embodiments, the first and second electronic components are placed on the substrate such that the terminal of the first electronic component is further aligned with the first conductive pad and the terminal of the second electronic component is further aligned with the second conductive pad. It can be appreciated that the first electronic component may have two or more terminals, while the terminal being in contact with the second solder paste is one of the two or more terminals. Similarly, the second electronic component may have two or more terminals, while the terminal being in contact with the second solder paste is one of the two or more terminals. In step 206, the second solder paste is reflowed to mount the first and second electronic components to the substrate. In the following, the steps of the method shown in FIG. 2 will be further illustrated in detail with reference to FIGS. 3A to 3F.

Specifically, as shown in FIG. 3A, a substrate 300 is provided, which includes a first conductive pad 310 and a second conductive pad 320. It should be appreciated that the first and second conductive pads may take any suitable shapes, with a rounded rectangle being preferred. The conductive pad 310 is used to mount a terminal of a first electronic component (not shown), and the conductive pad 320 is used to mount a terminal of a second electronic component (not shown) in a later step. Referring to FIG. 3A, a distance D2 between the first conductive pad 310 and the second conductive pad 320 can be small, for example, smaller than 65 µm, preferably in a range of 40 µm to 60 µm. It should be noted that FIG. 3A is for illustrative purpose only, the substrate 300 may include any number of conductive pads which are arranged in any desired layouts, and one or more additional conductive pads on the substrate 300 may also be used to mount other terminals of the first electronic component or the second electronic component, or to mount terminals of other electronic components. In some examples, the conductive pads 310 and 312 may be formed of metal such as copper as contact pads.

Referring to FIG. 3B, a first solder paste 330 is applied onto the first conductive pad 310, such as by a depositing process. In some other embodiments, the first solder paste 330 is applied or otherwise formed onto the first conductive pad 310 by stencil printing, screen printing, pin transfer, or jet printing. It can be appreciated that there may be a number of conductive pads on the substrate 300, and the formation of the first solder paste on the substrate 300 can be conducted at the same time during the same process.

Referring to FIG. 3C, the first solder paste 330 on the first conductive pad 310 is reflowed to form a first solder layer 331. In some embodiments, the first solder paste 330 on the first conductive pad 310 is heated in an oven or using a hot-air reflow system, causing it to melt and then form the first solder layer 331 after a subsequent cooling phase. In other words, the reflow process may increase the temperature of the first solder paste 330 to exceed its melting temperature. In some embodiments, the first solder layer 331 may harden and solidify after the reflow process. In other embodiments, the first solder layer 331 may remain in a mixed state, with both solid and liquid phases, after the reflow process.

It can be appreciated that after the reflow process, the first solder paste 330 may transform into the first solder layer 331 which may take a certain space and area on the first conductive pad 310. Thus, an amount of the first solder paste 330 applied or otherwise formed onto the first conductive pad 310 may be controlled to avoid an excess portion of the first solder paste 330 flows substantially out of the first conductive pad 310 and onto a surface of the substrate 300. As shown in FIG. 3C, the first solder layer 331 may have a convex shape, or form a substantially a flat plane, depending on a material (especially a surface tension) of the first solder layer 331. In some embodiments, the amount of the first solder paste 330 applied or otherwise formed onto the first conductive pad 310 may be controlled to form a first solder layer 331 with a height ranging from 5 to 25 um.

Next, as shown in FIG. 3D, a second solder paste 340 is applied to both the first solder layer 331 on the first conductive pad 310, and onto the second conductive pad 320. The second solder paste 340 may differ from the first solder paste 330 in composition. Specifically, the first solder paste 330 may have a higher melting temperature than the second solder paste 340. As such, if the substrate 300 is heated to a temperature between the melting temperature of the first solder layer 331 and the melting temperature of the second solder paste 340, the second solder paste 340 may melt, while the first solder layer 331 may not. In some embodiments, the first solder paste is Sn5Sb solder with a melting temperature of approximately 243 °C or Sn10Sb solder with a melting temperature of approximately 248 °C. The second solder paste is SAC305 solder with a melting temperature of approximately 217 °C.

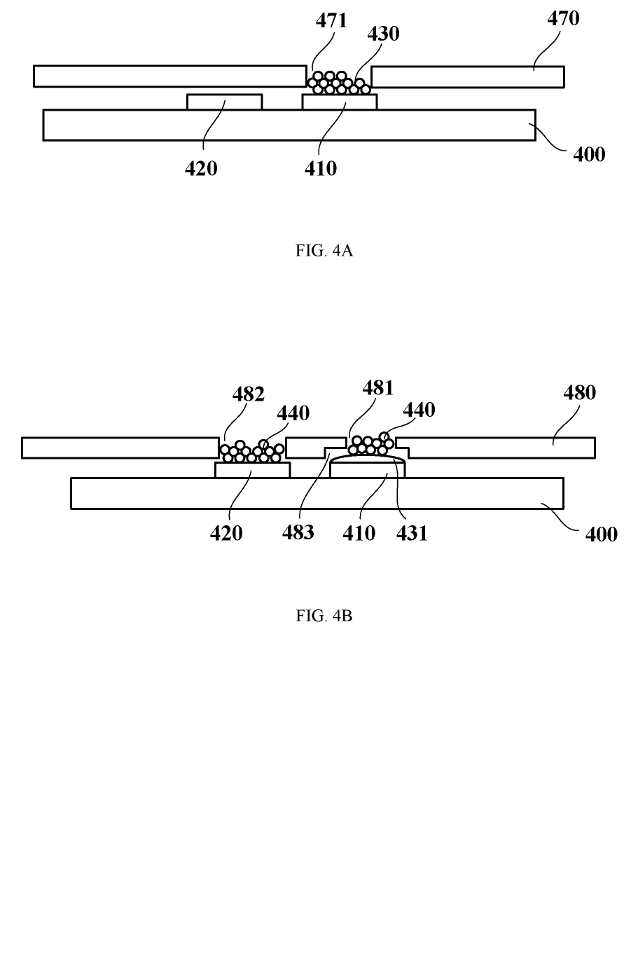

As the second solder paste 340 is formed on both the first conductive pad 310 with the first solder layer 331 and the second conductive pad 320 without the first solder layer 331, an amount of the second solder paste 340 on the first conductive pad 310 may be different from an amount of the second solder paste 340 on the second conductive pad 320. In some embodiments, the amount of the second solder paste 340 applied onto the first solder layer 331 is less than the amount of the second solder paste 340 applied onto the second conductive pad 320. This ensures that there is no significant height difference between the solder layers formed on the two conductive pads 310 and 320. In this way, the preformed first solder layer 331 does not affect substantially the height alignment between adjacent terminals of the two electronic components to be mounted. In some embodiments, the amount of the second solder paste 340 applied onto the first solder layer 331 is less than the amount of the first solder paste 330 applied onto the first conductive pad 310, ensuring that the first solder layer 331 has a sufficient height to maintain an appropriate distance between the reflowed solder layers beneath the adjacent terminals of the electronic components. In some embodiments, in addition to the first solder layer 331, the second solder paste 340 may also be formed on the first conductive pad 310 (e.g., with a small amount of the second solder paste 340 flowing downstream), but its main portion remains positioned above the first solder layer 331. In some embodiments, the second solder paste 340 is applied by stencil printing on the first solder layer 331 and the second conductive pad 320. A stencil used for applying solder paste will be illustrated in more details as shown in FIG. 4A and 4B. It can be appreciated that other deposition processes such as pin transfer, or jet printing can be used for applying the second solder paste 340.

Referring to FIG. 3E, a first electronic component 350 and a second electronic component 360 are placed onto the substrate 300 such that a terminal 351 of the first electronic component 350 is in contact with the second solder paste 340 on the first solder layer 331, and a terminal 361 of the second electronic component 360 is in contact with the second solder paste 340 on the second conductive pad 320. In some embodiments, the terminals 351 and 361 may be aligned with the first and second conductive pads, respectively. In some other embodiments, the terminal 351 may be disposed on the first conductive pad 310 with an offset, which may not affect the connection between the terminal 351 and the first conductive pad 310 via the first solder layer 331 and the second solder paste 340. Similarly, the terminal 361 may be disposed on the second conductive pad 320 with an offset, which may not affect the connection between the terminal 361 and the second conductive pad 320 via the second solder paste 340. As aforementioned, it should be noted that, although the first and second electronic components 350 and 360 shown in FIG. 3E each have only one terminal, they may include one or more additional terminals to form additional electrical connections to other conductive pads on the substrate 300. In a preferred embodiment, the other terminals of the first electronic component 350 may be placed and mounted on another conductive pad on the substrate 300 via another first solder layer and another second solder paste, similarly as the terminal 351; furthermore, the other terminals of the second electronic component 360 may be placed and mounted on another conductive pad on the substrate 300 via another second solder paste, similarly as the terminal 361. In this way, the electronic components 350 and 360 may not tilt relative to the surface of the substrate 300.

Next, referring to FIG. 3F, the second solder paste 340 is reflowed to form a second solder layer 341 on the first solder layer 331 and the second conductive pad 320, thereby mounting the first electronic component 350 and the second electronic component 360 onto the substrate 300. For example, the substrate 300 may be heated to increase its temperature to a temperature between the melting temperature of the second solder paste 340 and the melting temperature of the first solder layer 331. Taking the terminal 361 as an example, the second solder paste 340 beneath the terminal 361 is reflowed, mounting the terminal 361 to the substrate 300. Specifically, the terminal 361 is metallurgically bonded to the second solder layer 341, thereby establishing both electrical and mechanical connections to the second conductive pad 320 on the substrate 300. Similarly, the terminal 351 of the first electronic component 350 is metallurgically bonded to the second solder layer 341 on the first solder layer 331, thereby electrically and mechanically connecting it to the first conductive pad 310 on the substrate 300. During the reflow process, the second solder paste 340 may melt and flow to cover a larger area. However, the second solder paste 340 may not flow out of the respective conductive pads 310 and 320, to avoid undesired electrical connection to the adjacent conductive pad. As mentioned earlier, in some embodiments, a portion of the first solder paste 330 of the first solder layer 331 may also flow slightly during the reflowing. However, since the first solder paste 330 has already been reflowed and has a higher melting temperature, its flow is limited.

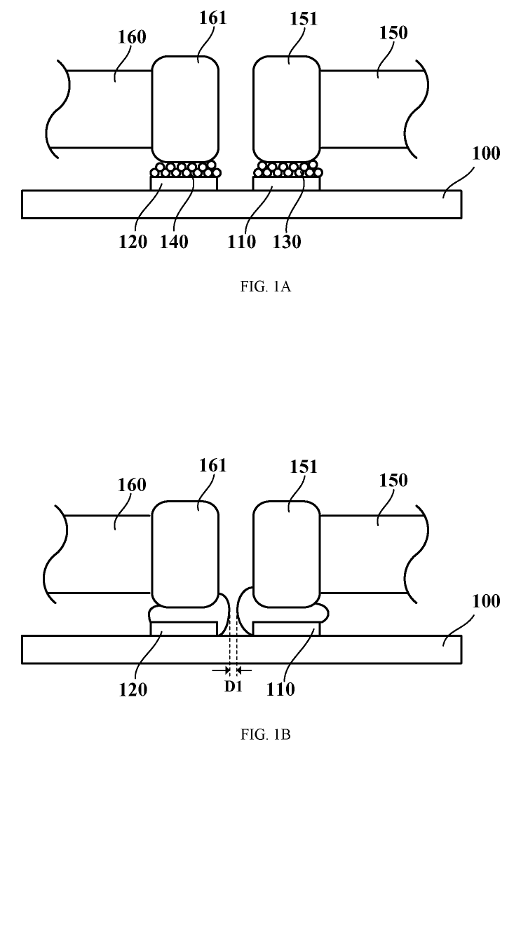

Due to the presence of the first solder layer 331 and/or the different amounts of the second solder paste 340 applied onto the first solder layer 331 and the second conductive pad 320, a total amount of reshaping of the second solder paste 340 is smaller, and a distance D1 between the reflowed solder paste 340 under the terminal 351 and the terminal 361 is greater, compared to that only one type of solder paste is applied onto the conductive pads, such as the solder paste under the terminals 151 and 161 shown in FIG. 1B. As a result, the solder paste beneath the adjacent terminals of the electronic components are less likely to be connected with each other and form a solder bridge or short circuits.

FIGS. 4A and 4B illustrate sectional views of two steps for applying the solder paste in the method shown in FIG. 2, according to another embodiment of the present application.

Referring to FIG. 4A, a first stencil 470 is used to apply a first solder paste 430 onto a first conductive pad 410. The first stencil 470 is placed on the substrate with an opening 471 in the first stencil 470 align with the first conductive pad 410. The first solder paste 430 is then applied through the opening 471, directly onto the first conductive pad 410. Referring to FIG. 4B, a second stencil 480 is used to apply a second solder paste 440 onto both a second conductive pad 420 and a first solder layer 431 transformed from the first solder paste by reflowing. Specifically, the second stencil 480 is placed on the substrate 400 to align a first opening 481 and a second opening 482 of the second stencil 480 with the first conductive pad 410 and the second conductive pad 420, respectively. The second solder paste 440 is applied onto the first solder layer 431 through a first opening 481 in the second stencil 480, and to the second conductive pad 420 through a second opening 482 in the second stencil 480. As shown in FIG. 4B, the second stencil 480 includes a recessed portion 483 around the first opening 481, which is sized and shaped to accommodate the first solder layer 431 at least partially during the paste applying process. As a result, the application of the second solder paste 440 can still be performed using conventional paste dispensing methods, such as screen printing, and the height difference between the first and second conductive pads 410 and 420 caused by the first solder layer 431 may not adversely affect the application of the second solder paste 440. The recessed portion 483 can have any shape suitable for receiving the first solder layer 431 during the paste application process. It can be appreciated that the shape, height or size of the recessed portion 483 may vary according to the shape or size of the first solder layer 431 formed on the first conductive pad 410. In some embodiments, the recessed portion may have a diameter or width which is greater than and proportional to that of the first opening 481. In some examples, the diameter or width of the recessed portion may be 1.1 to 2 times that of the first opening 481. It can be appreciated that the combination of the recessed portion and the first opening 481 not only allows the first solder paste and the second solder paste to be applied onto the first conductive pad, but also prevents them from flowing outside of the first conductive pad during the application process.

It can also be appreciated that the openings 471, 481, and 482 can be sized and shaped appropriately to achieve the desired form of the applied solder paste. In some embodiments, the first opening 481 is smaller than the second opening 482. Preferably, a screen-printing process is used with the first and second stencils to deposit a desired amount of solder paste. In some embodiments, the solder paste material is applied across the top surface of the first and second stencils using a squeegee. Preferably, the first and second stencils are made from materials such as metal. The stencils are typically fabricated using standard methods, such as electroforming. It will be appreciated that the thickness of the first and second stencils can vary depending on the amount of solder paste to be applied. As previously mentioned, FIGS. 4A and 4B are provided for illustrative purposes only. The substrate 400 may include any number of conductive pads, and the first and second stencils may also have corresponding number of openings to apply different solder pastes to these pads or to any layers formed on these pads.

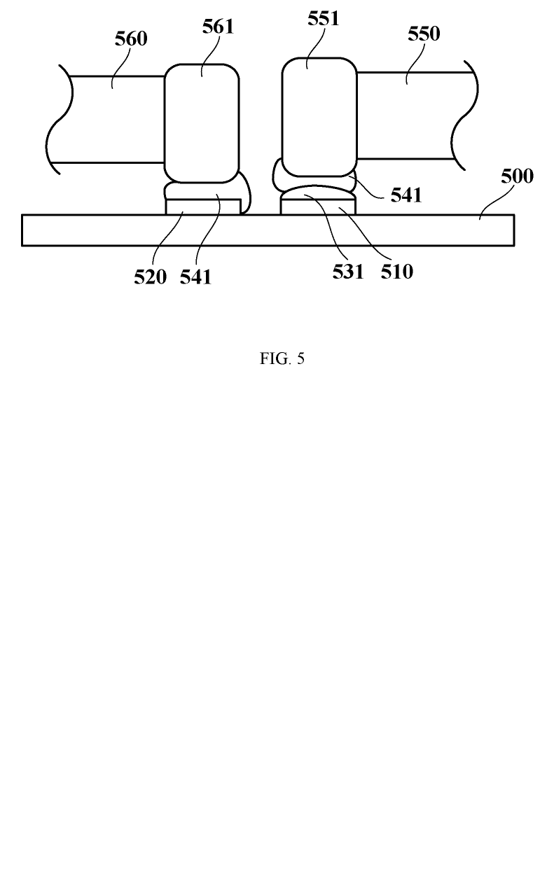

FIG. 5 illustrates a partial sectional view of an electronic package formed using the method shown in FIG. 2, according to an embodiment of the present application. As depicted in FIG. 5, the electronic package includes a substrate 500 and at least two electronic components mounted onto the substrate 500. A first conductive pad 510 and a second conductive pad 520, adjacent to the first conductive pad 510, are positioned on the substrate 500. The electronic components are electrically and mechanically connected to the substrate 500 through the reflowed solder layers. Specifically, the electronic package has a first solder layer 531 formed on the first conductive pad 510, and a second solder layer 541 formed on both the first solder layer 531 and the second conductive pad 520. The first electronic component 550 is positioned on the substrate 500 with its terminal 551 mounted on the first conductive pad 510 via the first solder layer 531 and the second solder layer 541. The second electronic component 560 is positioned on the substrate 500 with its terminal 561 mounted on the second conductive pad 520 via the second solder layer 541.

It will be appreciated that the substrate 500 may include any number of conductive pads, which are arranged in any desired layouts, and one or more additional conductive pads on the substrate 500 may also be used to mount other terminals of the first electronic component 550 or the second electronic component 560, or to mount terminals of other electronic components. Furthermore, other adjacent conductive pads on the substrate 500 may have similar solder layers to those formed beneath the terminals 551 and 561.

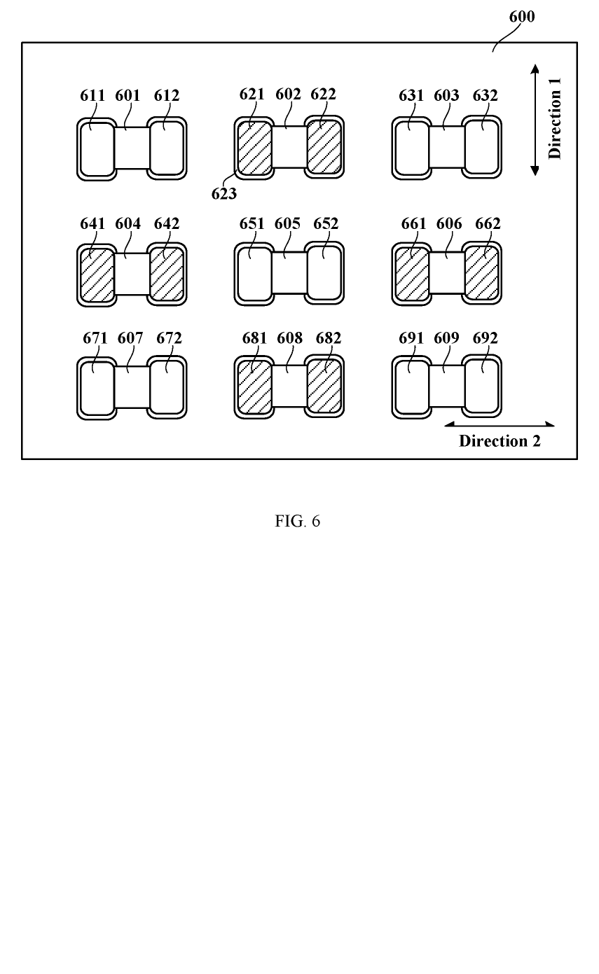

FIG. 6 illustrates a partial top view of an electronic device according to an embodiment of the present application. As shown in FIG. 6, the electronic device includes a substrate 600 with a plurality of components 601 to 609 mounted on it. Each of the electronic components 601 to 609 are electrically and mechanically connected to the substrate 600 through two terminals. Taking two adjacent electronic components 604 and 605 as an example, a terminal 651 of the component 605 is positioned adjacent to a terminal 642 of the component 604. The terminal 651 is electrically and/or mechanically connected to the substrate 600 through the same solder layer structure as the bi-layer solder layer structure beneath the terminal 551, as described above with reference to FIG. 5, while the terminal 642 is electrically and/or mechanically connected to the substrate 600 through the same solder layer structure as the single solder layer structure beneath the terminal 561. As a result, the solder layers beneath the adjacent terminals 651 and 642 are less likely to come into contact with each other and form a solder bridge. Thus, compared to traditional solder layer structure, the electronic device illustrated in FIG. 6 reduces the risk of solder bridges and short circuit defects between adjacent electronic components.

Further referring to FIG. 6, the substrate 600 includes an electronic component 602 adjacent to the electronic component 605 in direction 1, which is perpendicular to direction 2 in which the electronic components 604 and 605 extend. A terminal 621 of the electronic component 602 is electrically and/or mechanically connected to a conductive pad 623 on the substrate 600 through the same solder layer structure as the single solder layer structure beneath the terminal 642. The process for forming this structure is similar to the method used to form the solder layer beneath the terminal 642, and involves the following steps. First, a second solder paste is applied to the conductive pad 623; then, the electronic component 602 is placed onto the substrate 600 such that the terminal 621 is in contact with the second solder paste applied onto the conductive pad 623. Finally, the second solder paste is reflowed to form a secure connection between the terminal 621 and the conductive pad 623. For the reasons mentioned above, the solder paste beneath adjacent terminals 651 and 621 are less likely to come into contact with each other and form a solder bridge. It can be appreciated that the shape and size of the terminals and conductive pads on structure 600 are for illustrative purposes only. The electronic device 600 can also be configured with terminals or conductive pads of different shapes or sizes.

Further referring to FIG. 6, considering the solder layer structure below the terminal 651, a terminal 681 adjacent to the terminal 651 may have the same solder layer structure as that beneath the terminal 621 to reduce the risk of solder bridges or short circuit defects. In some embodiments, each solder layer structure beneath a terminal is different from the respective solder layer structures beneath all terminals adjacent to the terminal. Specifically, in some embodiments, terminals 611, 612, 631, 632, 652, 671, 672, 691 and 692 may have the same solder layer structure as that beneath the terminal 651, while terminals 622, 641, 642, 661, 662, 681 and 682 may have the same solder layer structure as that beneath the terminal 621. It can be appreciated that the distribution of the different solder layer structures beneath these terminals can be realized in various ways, all of which may ensure that the solder layer structures beneath adjacent terminals of different components are similar to those beneath the terminals 651 and 621.

The method of forming the electronic device 600 is generally corresponding to the methods described above. First, the substrate 600 with a plurality of conductive pads is provided. Next, a first solder paste is applied onto a first set of conductive pads on the substrate 600, where a solder layer structure similar to that beneath terminal 651 will be formed. Then, the first solder paste on the first set of conductive pads is reflowed to form a first solder layer on each of the first set of conductive pads. After that, a second solder paste is applied onto all of the first solder layers and a second set of conductive pads on the substrate 600, where a solder layer structure similar to that beneath terminal 621 will be formed. A plurality of electronic components are then placed on the substrate 600, with their terminals respectively in contact with the second solder paste on the first solder layers and the second set of conductive pads. Finally, the second solder paste is reflowed to mount these electronic components to the substrate 600.

In some embodiments, stencils may be used to apply the first and/or second solder pastes. The stencil used for applying the first solder paste may have a plurality of openings corresponding to the first set of conductive pads on the substrate. The stencil used for applying the second solder paste may have openings corresponding to both the first and second sets of conductive pads on substrate 600, with the openings for the first set of conductive pads being smaller than the opening for the second set of conductive pads.

As illustrated above, compared to the conventional solder paste setting, the present application reduces the risk of solder bridges or short circuit defects between adjacent electronic components.

The discussion herein included numerous illustrative figures that showed various portions of an electronic package and method of forming thereof. For illustrative clarity, such figures did not show all aspects of each example assembly. Any of the example assemblies and/or methods provided herein may share any or all characteristics with any or all other assemblies and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for forming an electronic package, comprising:
providing a substrate, wherein the substrate comprises a first conductive pad where a terminal of a first electronic component is to be mounted and a second conductive pad where a terminal of a second electronic component is to be mounted, wherein the first conductive pad is adjacent to the second conductive pad;
forming a first solder paste on the first conductive pad;
reflowing the first solder paste on the first conductive pad to form a first solder layer;
forming a second solder paste on the first solder layer and on the second conductive pad, respectively;
placing the first electronic component and the second electronic component on the substrate such that the terminal of the first electronic component is in contact with the second solder paste on the first solder layer, and the terminal of the second electronic component is in contact with the second solder paste on the second conductive pad; and
reflowing the second solder paste to mount the first electronic component and the second electronic component onto the substrate.

2. The method of claim 1, wherein the first solder paste is different from the second solder paste.

3. The method of claim 1, wherein the first solder paste has a higher melting temperature than the second solder paste.

4. The method of claim 1, wherein an amount of the second solder paste formed on the first solder layer is less than an amount of the second solder paste formed on the second conductive pad.

5. The method of claim 1, wherein an amount of the second solder paste formed on the first solder layer is less than an amount of the first solder paste formed on the first conductive pad.

6. The method of claim 1, wherein forming a second solder paste comprising:
placing a stencil on the substrate to align a first opening and a second opening of the stencil with the first conductive pad and the second conductive pad, respectively, wherein the first opening is smaller than the second opening; and
dispensing the second solder paste on the first solder layer through the first opening and the second solder paste on the second conductive pad through the second opening.

7. The method of claim 6, wherein the stencil has a recessed portion around the first opening for at least partially receiving the first solder layer.

8. The method of claim 1, wherein the first solder paste is selected from a group consisting of Sn5Sb solder and Sn10Sb solder.

9. The method of claim 1, wherein the second solder paste is SAC305 paste.

10. The method of claim 1, wherein the substrate comprises a third conductive pad where a terminal of a third electronic component is to be mounted, the third conductive pad being adjacent to the first conductive pad along a direction perpendicular to the direction extending along the first conductive pad and the second conductive pad, and the method further comprises:
forming a second solder paste on the third conductive pad;
placing the third electronic component on the substrate such that the terminal of the third electronic component is in contact with the second solder paste on the third conductive pad; and
reflowing the second solder paste to mount the third electronic component onto the substrate.

11. An electronic package formed with the method of claim 1.

12. An electronic device, comprising:
a substrate;
a first conductive pad and a second conductive pad on the substrate, wherein the first conductive pad is adjacent to the second conductive pad;
a first solder layer formed on the first conductive pad;
a second solder layer formed on the first solder layer and on the second conductive pad, respectively;
a first electronic component with a terminal mounted on the first conductive pad via the first solder layer and the second solder layer;
a second electronic component with a terminal mounted on the second conductive pad via the second solder layer.

13. The electronic device of claim 12, wherein the first solder layer is formed from a first solder paste and the second solder layer is formed from a second solder paste different from the first solder paste.

14. The electronic device of claim 13, wherein the first solder paste has a higher melting temperature than the second solder paste.

15. The electronic device of claim 13, wherein an amount of the second solder paste used to form the second solder layer on the first solder layer is smaller than an amount of the second solder paste used to form the second solder layer on the second conductive pad.

16. The electronic device of claim 13, wherein an amount of the second solder paste used to form the second solder layer on the first solder layer is smaller than an amount of the first solder paste used to form the first solder layer on the first conductive pad.

17. The electronic device of claim 13, wherein the first solder paste is selected from a group consisting of Sn5Sb solder and Sn10Sb solder with a melting temperature.

18. The electronic device of claim 13, wherein the second solder paste is SAC305 paste with a melting temperature.

19. The electronic device of claim 12, further comprising:
a third conductive pad on the substrate, wherein the third conductive pad is adjacent to the first conductive pad along a direction perpendicular to the direction extending along the first conductive pad and the second conductive pad; and
wherein the second solder layer is also formed on the third conductive pad, and the electronic device further comprises a third electronic component with a terminal mounted on the third conductive pad via the second solder layer.
